(19) United States
(12) Patent Application Publication
(10) Pub. No.: US 2013/0154696 A1
(43) Pub. Date: Jun. 20, 2013

(54) CHARGE PUMP CIRCUIT AND PHASE LOCK LOOP CIRCUIT

(71) Applicant: Yi-Lung Chen, Keelung City (TW)

(72) Inventor: Yi-Lung Chen, Keelung City (TW)

(73) Assignee: ISSC TECHNOLOGIES CORP., Hsinchu City (TW)

(21) Appl. No.: 13/327,765

(22) Filed: Dec. 16, 2011

(51) Int. Cl. H03L 7/093; G05F 3/02

(52) U.S. Cl. 327/157; 327/536

(57) ABSTRACT

A charge pump circuit is provided. The charge pump circuit includes a current driving unit, a current draining unit, a switch, and a voltage splitting circuit. The current driving circuit receives a first control signal to transmit a driving current to the first end or the second end according to the first control signal. The current draining unit receives a second control signal to drain a draining current from the first end or the second end according to the second control signal. The switch is coupled between the first end and the second end, and the switch is turned on or turned off according to a power down control signal. The voltage splitting circuit receives a reference power voltage, and is coupled to the first end. The voltage splitting circuit provides a splitting power to the first end by splitting the voltage of the reference power voltage.

### BACKGROUND OF THE INVENTION

1. Field of the Invention

The invention generally relates to a charge pump circuit, in particular, to a charge pump circuit applied to a phase lock loop.

2. Description of Related Art

A charge pump circuit is usually applied to a part of a circuit, especially to a terminal of the circuit. When the voltage of the terminal is required to be adjusted, the charge pump circuit may be used to charge or discharge the terminal for adjusting the voltage of the terminal.

FIG. 1 shows a charge pump circuit 100 of a related art. Please refer to FIG. 1. The charge pump circuit 100 includes a current source A1, a current source A2, a switch SW1, and a switch SW2. Wherein, the switches SW1 and SW2 respectively receive a first control signal CTR1 and a second control signal CTR2. Then, the switch SW1 connects the current path where a driving current flows from the current source A1 to a terminal CTL. Likewise, the switch SW2 turns on the path where a draining current flows from the terminal CTL to the current source A2.

In the actual operation, when charging the terminal CTL, the switch SW1 is turned on, and the current source A1 transmits a driving current I1 to the terminal CTL to drive up the voltage of the terminal CTL. Besides, when discharging the terminal CTL, the switch SW2 is turned on, and the current source A2 drains a current I2 from the terminal CTL to drive down the voltage of the terminal CTL.

Nevertheless, when charging the terminal CTL, the switch SW2 is turned off to disconnect the current path where the current I2 flows and the current source A2 stops working. Similarly, when discharging the terminal CTL, the current source A1 stops working. Therefore, every time when the terminal CTL switches the function between charging the terminal CTL and discharging the terminal CTL, the current sources A1 and A2 require a period of time to revive from stopping working, and the charging or discharging time of the terminal CTL is long because of the reviving time.

### SUMMARY OF THE INVENTION

Accordingly, the present invention is directed to a charge pump circuit, and further to generate an output voltage quickly.

The present invention is directed to a phase lock loop circuit, and further to increase the speed to lock a phase of a signal.

According to an embodiment of the present invention, a charge pump circuit is provided. The charge pump circuit includes a current driving unit, a current draining, a switch, and a splitting voltage circuit. Wherein, the current driving unit is coupled to a first terminal and a second terminal. The current driving unit receives a first control signal, and the current driving unit transmits a driving current to the first terminal or the second terminal according to the first control signal. The current draining unit is coupled to the first terminal and the second terminal. The current draining unit receives a second control signal, and the current draining unit drains a draining current from the first terminal or the second terminal according to the second control signal. The switch is coupled between the first terminal and the second terminal, and the switch is turned on or turned off according to a power down control signal. The splitting voltage circuit receives a reference power voltage, and the splitting voltage circuit is coupled to the first terminal. The splitting voltage circuit provides a splitting power depending on the reference power voltage.

According to an embodiment of the present invention, a phase lock loop circuit is provided. The phase lock loop circuit includes a phase frequency detector, a charge pump circuit, a low pass filter, a voltage control oscillator, and a frequency divider. The phase frequency detector receives a reference signal and a frequency dividing signal. The phase frequency detector outputs a first control signal and a second control signal according to the comparison of the phase and the frequency between the reference signal and the frequency dividing signal. A charge pump circuit outputs a charge pump voltage according to the first control signal and the second control signal wherein the charge pump circuit includes a current driving unit, a current draining unit, a switch, and a splitting voltage circuit. The current driving unit receives a first control signal, and the current driving unit transmits a driving current to the first terminal or the second terminal according to the first control signal. The current draining unit is coupled to the first terminal and the second terminal. The current draining unit receives a second control signal, and the current draining unit drains a draining current from the first terminal or the second terminal according to the second control signal. The switch is coupled between the first terminal and the second terminal, and the switch is turned on or turned off according to a power down control signal. The splitting voltage circuit receives a reference power voltage, and the splitting voltage circuit is coupled to the first terminal. The splitting voltage circuit provides a splitting power depending on the reference power voltage. The low pass filter receives the charge pump voltage, and the low pass filter outputs a control voltage depending on the charge pump voltage. The voltage control oscillator receives the control voltage, and the voltage control oscillator outputs a voltage control signal according to the control voltage, wherein the frequency of the voltage control signal is a multiple of the frequency of the reference signal. The frequency divider receives the voltage control signal. The frequency divider outputs the frequency dividing signal according to the voltage control signal and according to the multiple between the frequency of the voltage control signal and the frequency of the reference signal.

Based on the description above, because the invention includes a switch and a splitting circuit, a splitting power is supplied to the first terminal of the charge pump circuit. After the charge pump circuit is initiated, the voltage of the first terminal corresponds with the second terminal through the switch which is turned on. Thus, the charge pump circuit stabilizes the output voltage thereof faster.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows a charge pump circuit of a related art.

FIG. 2 shows function blocks of a charge pump circuit according to an embodiment of the invention.

FIG. 3 shows a schematic circuit of the charge pump circuit according to an embodiment of the invention.

FIG. 4 shows a schematic view of a phase lock loop circuit according to an embodiment of the invention.

FIG. 5 shows the operation waveform of the output voltage of the charge pump circuit according to an embodiment of the invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

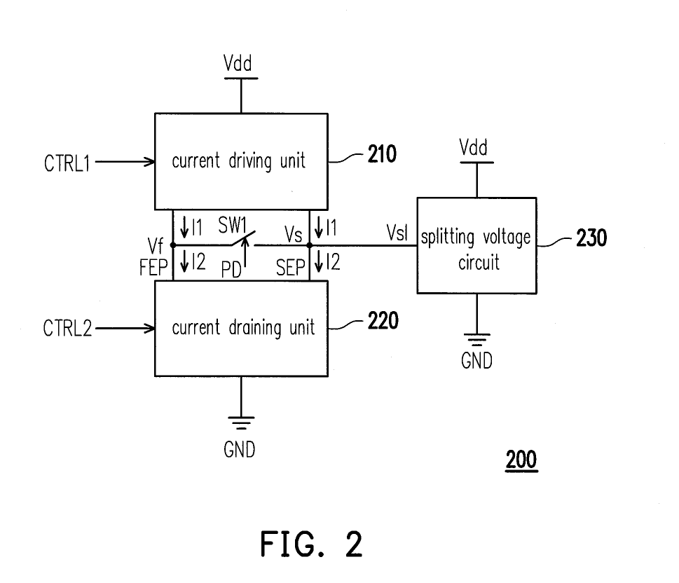

FIG. 2 shows function blocks of a charge pump circuit 200 according to an embodiment of the invention. Please refer to FIG. 2. The charge pump circuit 200 includes a current driving unit 210, a current draining unit 220, a splitting voltage circuit 230, and a switch SW1. Wherein, the current driving unit 210 and the current draining unit 220 are respectively coupled to a terminal FEP and a terminal SEP. The current driving unit 210 receives the control signal CTRL1, and supplies a driving current I1 to the terminal FEP or SEP according to the control signal CTRL1. Likewise, the current draining unit 220 receives a control signal CTRL2, and the current draining unit 220 drains a current I2 from the terminal FEP or SEP. The switch SW1 is coupled between the terminal FEP and the terminal SEP, and the switch SW1 electrically connects or disconnects between the two terminals (terminal FEP and SEP) according to a power down control signal PD. Besides, the splitting voltage circuit 230 receives a reference power voltage Vdd, and supplies a splitting power Vsl depending on the reference power voltage Vdd. The splitting voltage circuit 230 is coupled to the terminal FEP, and the splitting voltage circuit 230 supplies the splitting power Vsl to the terminal FEP through the terminal SEP and the switch SW1.

In the real operation, when the charge pump circuit 200 is disabled, that is, when the charge pump circuit 200 is not initiated, the switch SW1 is turned off according to the power down control signal PD. Besides, when the charge pump circuit 200 is enabled, the switch is turned on according to the power down signal PD. When the charge pump circuit 200 is initiated, the splitting voltage circuit 230 supplies an initial splitting power Vsl to the terminal SEP and FEP, wherein the splitting power Vsl is, for example, half of the reference power voltage Vdd. Then, the current driving unit 210 and the current draining unit 220 are respectively controlled by the control signal CTRL1 and CTRL2 to respectively charge or discharge the terminal FEP, and the output voltage Vf of the terminal FEP is driven up or driven down.

If the current driving unit 210 is controlled by the control signal CTRL1 to transmit the driving current I1 to the terminal FEP for charging the terminal FEP, that is, the control signal CTRL1 is, for example, at a high voltage level, the output voltage Vf will be driven up. On the contrary, if the current draining unit 220 is controlled by the control signal CTRL2 to drain the draining current I2 from the terminal FEP for discharging the terminal FEP, that is, if the control signal CTRL2 is, for example, at a high voltage level, the output voltage Vf of the terminal FEP will be driven down. Besides, due to the serial connection between the terminal FEP and the terminal SEP through the switch SW1, the terminal voltage Vs of the terminal SEP is able to track the voltage which is equal to the output voltage Vf of the terminal FEP by the complementary operation of normal current path (the path through the terminal FEP) and dummy current path (the path through the terminal SEP).

At last, after finishing charging or discharging the terminal FEP, the control signals CTRL1 and CTRL2 are all at a low voltage level. At this time, the control signal CTRL1 allows the current driving unit 210 to disconnect the current path where the driving current I1 flows to the terminal FEP, and the control signal CTRL2 allows the draining current unit 220 to disconnect current path where the draining current I2 flows to the terminal FEP. Based on the complementary operation, the control signals CTRL1 and CTRL2 respectively allow the current driving unit 210 and the current draining unit 220 to connect the current paths where the driving current Il and the draining current I2 flow to the terminal SEP.

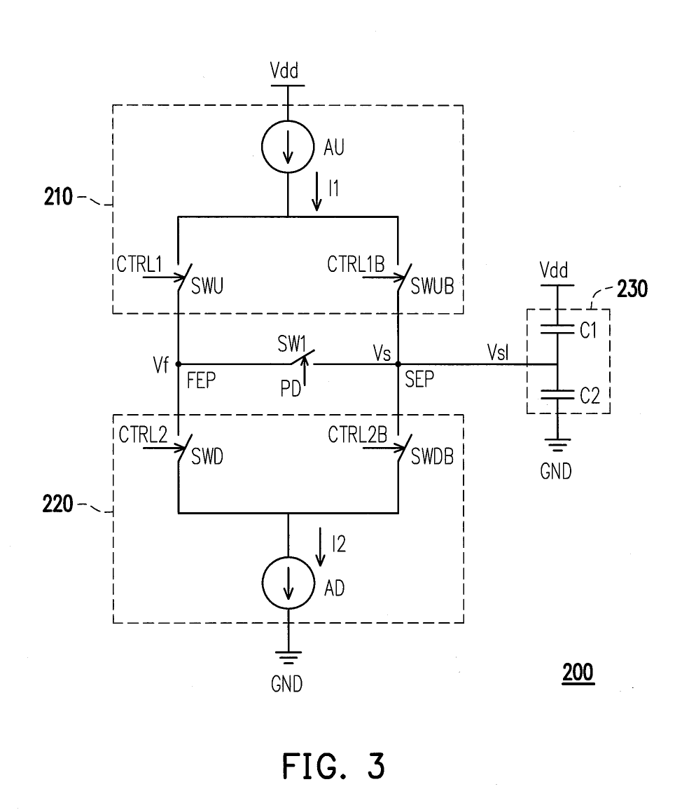

Furthermore, please refer to FIG. 3. FIG. 3 shows a schematic circuit of the charge pump circuit 200 according to an embodiment of the invention. The current driving unit 210 includes a driving current source AU, a driving switch SWU, and a driving switch SWUB. The driving current source AU receives the reference power voltage Vdd, and supplies the driving current I1 to the terminal FEP or SEP. The driving switch SWU is serially connected between the driving current source AU and the terminal FEP, and is turned on or turned off according to the control signal CTRL1. Likewise, the driving switch SWUB is serially connected between the driving current source AU and the terminal SEP, and is turned on or turned off according to the control signal CTRL2.

In the real operation, when charging the terminal FEP, the driving switch connects the current path where the driving current I1 flows from the driving current source AU to the terminal FEP according to the control signal CTRL1. Meanwhile, the driving switch SWUB disconnects the current path where the driving current I1 flows from the driving current source AU to the terminal SEP according to the control signal CTRL1B. Wherein, the phases of the control signal CTRL1B and the control signal CTRL1 are complementary. When discharging the terminal FEP, the driving switch SWU disconnects the current path where the driving current I1 flows from the driving current source AU to the terminal FEP according to the control signal CTRL1, and the driving switch SWUB connects the current path where the driving current I1 flows from the driving current source AU to the terminal SEP according to the control signal CTRL1B. Besides, after charging the terminal FEP, the driving switch SWU is turned on and the driving switch SWUB is turned off according to the control signals CTRL1 and CTRL1B respectively.

The current draining unit 220 includes a draining current source AD, a draining switch SWD, and a draining switch SWDB. The draining current source AD receives a ground voltage GND, and supplies the draining current I2 for charging or discharging the terminal FEP or SEP. The draining switch SWD is serially connected between the terminal FEP and the draining current source AD, and the draining switch SWDB is serially connected between the terminal SEP and the draining current source AD. The draining switches SWD and SWDB are respectively turned on or turned off according to the control signals CTRL2 and CTRL2B respectively.

When charging the terminal FEP, the draining switch SWD disconnects the current path where the draining current I2 flows from the terminal FEP to the draining current source AD according to the control signal CTRL2, and the draining switch SWDB connects the current path where the draining current I2 flows from the terminal SEP to the draining current source AD according to the control signal CTRL2B. Wherein, the phases of the control signal CTRL2B and the control signal CTRL2 are complementary. When discharging the terminal FEP, the draining switch SWD connects the current path where the draining current I2 flows from the terminal FEP to the draining current source AD according to the control signal CTRL2, and the draining switch SWDB disconnects the current path where the draining current I2 flows from the terminal SEP to the draining current source AD according to the control signal CTRL2B. At last, after finishing discharging the terminal FEP, the draining switch SWD is turned off and the draining switch SWDB is turned on respectively according to the control signal CTRL2 and the control signal CTRL2B.

In addition, the absolute value of the draining current I2 is equal to the absolute value of the driving current I1.

As described above, when charging the terminal FEP, a current path is formed from the driving current source AU through the driving switch SWU, the switch SW1, and the draining switch SWDB to the draining current source AD. When discharging the terminal FEP, a current path is formed from the driving current source AU through the driving switch SWUB, the switch SW1 and the draining switch SWD to the draining current source AD. In addition, after finishing charging or discharging the terminal FEP, a current path is formed from the driving current source AU through the driving switch SWUB and the draining switch SWDB to the draining current source AD. Therefore, the driving current source AU and the draining current source AD according to the embodiment of the invention never stop working after the charge pump circuit 200 is initiated. Thus, when the charge pump circuit 200 of this embodiment switches the function between charging the terminal FEP by the current driving unit 210 and discharging the terminal FEP by the current draining unit 220, no extra reviving time for current source (AU and AD) is required.

In addition, the splitting voltage circuit 230 includes a capacitor C1 and a capacitor C2. The capacitors C1 and C2 include first terminals which respectively receive the reference power voltage Vdd and the ground voltage GND. The capacitor C1 includes a second terminal which is coupled to a second terminal of the capacitor C2, and the splitting power Vsl is formed at the second terminal of the capacitors C1 and C2, that is , at the end point where the capacitor C1 is coupled to the capacitor C2. In an embodiment of the invention, the capacitor C1 may be formed by a p-type transistor, and the p-type transistor includes a source and a drain (the first terminal of the capacitor C1) to receive the reference power voltage Vdd. The capacitor C2 may be formed by an n-type transistor, and the n-type transistor includes a source and a drain (the first terminal of the capacitor C2) to receive the ground voltage GND. Additionally, the p-type transistor includes a gate (the second terminal of the capacitor C1) to be coupled to a gate of the n-type transistor (the second terminal of the capacitor C2).

When the charge pump circuit 200 is enabled, the splitting circuit 230 supplies the splitting power Vsl to the terminal FEP as an initial voltage of the terminal FEP through the switch SW1 which is turned on. In an embodiment of the invention, the splitting power Vsl is half of the reference power voltage Vdd. As described above, if the capacitors C1 and C2 are respectively formed by the p-type transistor and the n-type transistor, the size of the p-type transistor will be the same as the size of the n-type transistor for offering the splitting power Vsl with the voltage of half of the reference power voltage Vdd to the terminal FEP when the charge pump circuit 200 is initiated.

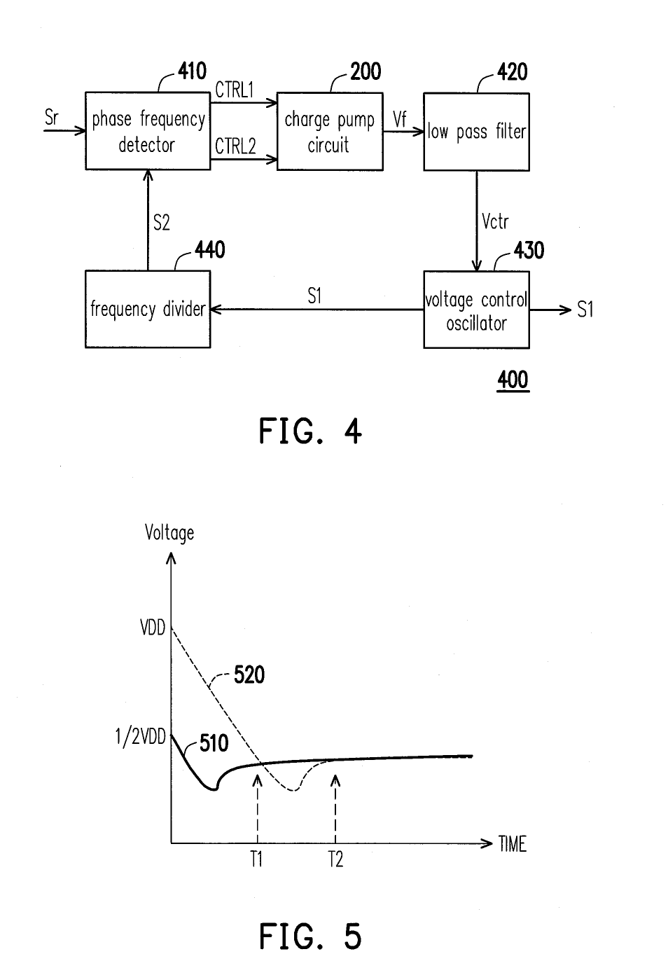

FIG. 4 shows a schematic view of a phase lock loop circuit 400 according to an embodiment of the invention. Please refer to the FIG. 4. The phase lock loop circuit 400 includes a phase frequency detector 410, a charge pump circuit 200, a low pass filter 420, a voltage control oscillator 430, and a frequency divider 440. Wherein, the phase frequency detector 410 receives a reference signal Sr and a frequency dividing signal S2. The phase frequency detector 410 outputs control signals CTRL1 and CTRL2 according to the comparison of the phase and frequency between the reference signal Sr and the frequency dividing signal S2. The charge pump circuit 200 outputs an output voltage Vf according to the control signals CTRL1 and CTRL2. The low pass filter 420 receives the output voltage Vf, and outputs a control voltage Vctr depending on the output voltage Vf. The voltage control oscillator 430 receives the control voltage Vctr, and outputs a voltage control signal S1 according to the control voltage Vctr. Wherein, the frequency of the voltage control signal S1 is a multiple of the frequency of the reference signal Sr. The frequency divider 440 receives the voltage control signal S1, and outputs the frequency dividing signal S2 according to the multiple between the frequency of the voltage control signal S1 and the frequency of the reference voltage signal Sr and according to the voltage control signal S1.

In the operation, firstly the phase frequency detector 410 compares the frequency of the reference signal Sr to the initial frequency of the frequency dividing signal S2. When the frequency of the frequency dividing signal S2 is lower than the frequency of the reference frequency Sr, the phase frequency detector 410 outputs the control signal CTRL1 with a high voltage level and the control signal CTRL2 with a low voltage level. In the meantime, the charge pump circuit 200 drives up the output voltage Vf in response to the control signals CTRL1 and CTRL2. Through the function of the low pass filter 420, the voltage control oscillator 430, and the frequency divider 440, the frequency dividing signal S2 is raised in response to the output voltage Vf which is driven up. On the other hand, when the frequency of the frequency dividing signal S2 is higher than the frequency of the reference signal Sr, the charge pump circuit 200 drives down the output voltage Vf, and further decreases the frequency of the frequency dividing signal S2. At last, if the frequency of the reference signal S2 is equal to the frequency of the frequency dividing signal S2, the phase frequency detector will output the control signals CTRL1 and CTRL2 with low voltage levels, and the charge pump circuit 200 will not adjust the output voltage Vf again.

The charge pump circuit 200 is the main trait of the invention. The specific description has been illustrated in the embodiments above. Please refer to the embodiments described in FIG. 2 and FIG. 3, and the description of the embodiments about the charge pump circuit 200 will not be repeated hereafter.

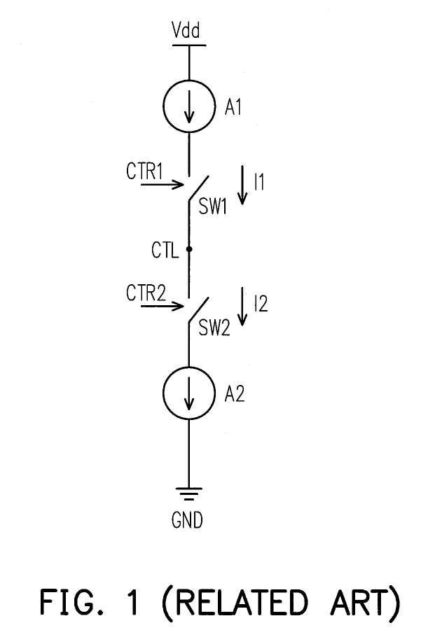

FIG. 5 shows the operation waveform of the output voltage Vf of the charge pump circuit 200 according to an embodiment of the invention. Please refer to FIG. 3 and FIG. 5. Wherein, a wave 510 describes the variation of the output voltage Vf according to an embodiment of the invention, and a wave 520 describes the variation of the output voltage of a charge pump circuit according to a prior art (e.g. the charge pump circuit 100 in FIG. 1). The charge pump circuit 200 according to the embodiment of the invention generates the output voltage which is about, for example, half of the reference power voltage Vdd, and the charging and discharging operations are finished at the time T1. The charge pump circuit according to a prior art generates an initial output voltage which is usually equal to the reference power voltage Vdd, and the charging or discharging operations are finished at the time T2. Therefore, it is observable that the settle time of the output voltage of the charge pump circuit according to an embodiment of the invention is shorter. In other words, through the charge pump circuit applied to a phase lock loop circuit, a required phase and a required frequency are tracked faster.

In summary, the charge pump circuit of the invention includes the switch and the splitting voltage circuit. When the charge pump circuit is initiated, the charge pump circuit is supplied the splitting power which is lower than the reference power voltage. Besides, the driving current source and the draining current source will not stop working if the charge pump circuit switches the function between charging and discharging. Furthermore, the reviving time of the driving current source and the draining current source is saved. Thus, the charge pump circuit of the invention shortens the time to charge or discharge the output terminal, and shortens the time that the phase lock loop circuit with the charge pump circuit of the invention tracks a required phase and a required frequency.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A charge pump circuit, comprising:
a current driving unit, coupled to a first terminal and a second terminal, the current driving unit receiving a first control signal, and the current driving unit transmitting a driving current to the first terminal or the second terminal according to the first control signal;
a current draining unit, coupled to the first terminal and the second terminal, the current draining unit receiving a second control signal, and the current draining unit draining a draining current from the first terminal or the second terminal according to the second control signal;
a switch, coupled between the first terminal and the second terminal, and the switch being turned on or turned off according to a power down control signal; and
a splitting voltage circuit, receiving a reference power voltage, and the splitting voltage circuit coupled to the first terminal, and the splitting voltage circuit providing a splitting power to the first terminal according to the reference power voltage.

2. The charge pump circuit as claimed in claim 1, wherein the switch is turned off according to the power down control signal when the charge pump circuit is disabled, and the switch is turned on according to the power down signal when the charge pump circuit is enabled.

3. The charge pump circuit as claimed in claim 1, wherein the current driving unit comprises:
a driving current source, receiving the reference power voltage, and the driving current source supplying the driving current;
a first driving switch, serially connected between the driving current source and the first terminal, the first driving switch receiving the first control signal, wherein the current path where the driving current flows from the driving current source to the first terminal is connected or disconnected by the first driving switch according to the first signal; and
a second driving switch, serially connected between the driving current source and the second terminal, the second driving switch receiving the signal of the reversed phase of the first control signal, wherein the current path where the driving current flows from the driving current source to the second terminal is connected or disconnected by the second driving switch according to the signal of the complementary phase of the first control signal.

4. The charge pump circuit as claimed in claim 1, wherein the current draining unit comprises:
a draining current source, receiving a ground voltage, and the draining current source drains the draining current;
a first draining switch, serially connected between the current draining source and the first terminal, and the first draining switch receiving the second control signal, wherein the current path where the draining current flows from the first terminal to the draining current source is connected or disconnected by the first draining switch according to the second control signal; and
a second draining switch, serially connected between the draining current source and the second terminal, the second draining switch receiving the signal of the reversed phase of the second control signal, wherein the current path where the draining current flows from the second terminal to the draining current source is connected or disconnected by the second draining switch according to the signal of the complementary phase of the second control signal.

5. The charge pump circuit as claimed in claim 1, wherein the splitting voltage circuit comprises:
a first capacitor, a first terminal of the first capacitor receiving the reference power voltage; and
a second capacitor, having a first terminal for receiving a ground voltage, and the second capacitor further having a second terminal coupled to a second terminal of the first capacitor, and the splitting power formed at the second terminal of the second capacitor.

6. The charge pump circuit as claimed in claim 5, wherein the first capacitor is a p-type transistor having a source and a drain receiving the reference power voltage, the second capacitor is a n-type transistor having a source and a drain receiving the ground voltage, wherein a gate of the p-type transistor is coupled to a gate of the n-type transistor.

7. A phase lock loop circuit, comprising:
a phase frequency detector, receiving a reference signal and a frequency dividing signal, the phase frequency detector outputting a first control signal and a second control signal according to the comparison of the phase and the frequency between the reference signal and the frequency dividing signal;
a charge pump circuit, outputting an output voltage according to the first control signal and the second control signal, wherein the charge pump circuit comprises:
a current driving unit, coupled to a first terminal and a second terminal, the current driving unit receiving the first control signal, and the current driving unit transmitting a driving current to the first terminal or the second terminal according to the first control signal;
a current draining unit, coupled to the first terminal and the second terminal, the current draining unit receiving the second control signal, and the current draining unit draining a draining current from the first terminal or the second terminal according to the second control signal;
a switch, coupled between the first terminal and the second terminal, and the switch turned on or turned off according to a power down control signal; and
a splitting voltage circuit, receiving a reference power voltage, and the splitting voltage circuit coupled to the first terminal, and the splitting voltage circuit providing a splitting power depending on the reference power voltage.
a low pass filter, receiving the output voltage, and the low pass filter outputting a control voltage depending on the output voltage;
a voltage control oscillator, receiving the control voltage, and the voltage control oscillator outputting a voltage control signal according to the control voltage, wherein the frequency of the voltage control signal is a multiple of the frequency of the reference signal; and
a frequency divider, receiving the voltage control signal, the frequency divider outputting the frequency dividing signal according to the voltage control signal and according to the multiple between the frequency of the voltage control signal and the frequency of the reference signal.

8. The phase lock loop circuit as claimed in claim 7, wherein the switch is turned off according to the power down control signal when the charge pump circuit is disabled, and the switch is turned on according to the power down signal when the charge pump circuit is enabled.

9. The phase lock loop circuit as claimed in claim 7, wherein the current driving unit comprises:
a driving current source, receiving the reference power voltage, and the driving current source supplying the driving current;
a first driving switch, serially connected between the driving current source and the first terminal, the first driving switch receiving the first control signal, wherein the current path where the driving current flows from the driving current source to the first terminal is connected or disconnected by the first driving switch according to the first control signal; and
a second driving switch, serially connected between the driving current source and the second terminal, the second driving switch receiving the signal of the reversed phase of the first control signal, wherein the current path where the driving current flows from the driving current source to the second terminal is connected or disconnected by the second driving switch according to the signal of the complementary phase of the first control signal.

10. The phase lock loop circuit as claimed in claim 7, wherein the current draining unit comprises:
a draining current source, receiving a ground voltage, and the draining current source drains the draining current;
a first draining switch, serially connected between the current draining source and the first terminal, and the first draining switch receiving the second control signal, wherein the current path where the draining current flows from the first terminal to the draining current source is connected or disconnected by the first draining switch according to the second control signal; and
a second draining switch, serially connected between the draining current source and the second terminal, the second draining switch receiving the signal of the reverse phase of the second control signal, wherein the current path where the draining current flows from the second terminal to the draining current source is connected or disconnected by the second draining switch according to the signal of the complementary phase of the second control signal.

11. The phase lock loop circuit as claimed in claim 7, wherein the splitting voltage circuit comprises:
a first capacitor, comprising a first terminal receiving the reference power voltage; and
a second capacitor, comprising a first terminal receiving a ground voltage, and the second capacitor comprising a second terminal coupled to a second terminal of the first capacitor, and the splitting power formed at the second terminal of the second capacitor.

12. The phase lock loop circuit as claimed in claim 11, wherein the first capacitor is a p-type transistor comprising a source and a drain receiving the reference power voltage, wherein the second capacitor is a n-type transistor comprising a source and a drain receiving the ground voltage, wherein a gate of the p-type transistor is coupled to a gate of the n-type transistor.
